(19) United States
(12) Patent Application Publication
(10) Pub. No.: US 2026/0305494 A1
(43) Pub. Date: Oct. 1, 2026

(54) VIA, VIA PAD, AND TRACE PAIR ARRANGEMENTS FOR DIFFERENTIAL SIGNALS

(71) Applicant: Intel Corporation, Santa Clara, CA (US)

(72) Inventors: Kai Xiao, Portland, OR (US); Fabio Alejandro Ruiz Molina, Zapopan (MX); Oscar Miramontes, Zapopan (MX); Carlos Alberto Lizalde Moreno, Guadalajara (MX); Raul Enriquez Shibayama, Zapopan (MX); Kuan-Yu Chen, Portland, OR (US); Jingbo Li, Portland, OR (US); Mo Liu, Santa Clara, CA (US); Silver Rodriguez Estrada, Zapopan (MX)

(73) Assignee: Intel Corporation, Santa Clara, CA (US)

(21) Appl. No.: 19/089,937

(22) Filed: Mar. 25, 2025

(51) Int. Cl. H01L 23/498

(52) U.S. Cl. CPC H10W 90/401; H10W 70/65; H10W 90/701

(57) ABSTRACT

An apparatus comprises a base component comprising a surface. The surface comprises a plurality of via pads and a plurality of interconnect pads arranged in a regular pattern of rows and columns orthogonal to the rows. A plurality of conductive vias extend below the surface. Each conductive via is coupled with one of the via pads. First and second interconnect pads in first and second rows in a first column are for coupling with a pair of differential signals. A first via pad in the first row intersects with the first interconnect pad. A second via pad in the second row contacts, partially overlaps, or spaced away from the second interconnect pad. The first via pad may be offset from a center line of the first row. The second via pad may be offset from a center line of the second row.

### BACKGROUND

In electronics manufacturing, integrated circuit (IC) chips and IC chip packages are communicatively connected to a base component, such as an interposer or a printed circuit board (PCB). Example technologies for connecting IC chips or packages with a base component include pin grid arrays (PGAs), ball grid arrays (BGAs), and land grid array (LGAs). A PGA has an array of pins arranged in a spatial pattern on an interface surface to conduct electrical signals between the IC device and the base component. In a BGA, the pins in the spatial pattern are replaced with pads. Each pad of a BGA has a solder ball on it. An LGA has an array of contacts or “lands” without solder balls. In each case, the contacts on the surface facing the base component are connected to a corresponding array of contacts on a facing surface of the IC device. The terms “pinfield,” “pinout,” and the like may be used to refer to arrays of connectors arranged in a spatial pattern on a surface regardless of whether the array includes pins or some other type of contact, e.g., pads, lands, or sockets. Similarly, the term “pin” may refer to any type of contact used to couple an IC chip or package with a base component.

The increasing demand for computing power in CPUs, GPUs, memory chips, IC packages, and the like presents challenges for connecting these devices to a base component. For example, in comparison with past systems, modern IC devices may have more and denser arrays of contacts. In particular, the pinfields on base components have become a busy traffic hub where various signaling interfaces and power domains are crowded together. Dense arrangements of interconnects may lead to various signal integrity issues, such as crosstalk and “fiber weave effect.” In addition, traces carrying differential signals within a base component may need long routing paths to accommodate modern CPUs and GPUs. Base components, such as PCBs, include layers with fibers which can result in fiber weave effect. Fiber weave effect can lead to timing skew between the positive and negative signals of a differential pair, which can impair signal integrity.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Views referred to as “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure. Further, where considered appropriate, reference labels have been repeated among the figures to indicate corresponding or analogous elements. In the figures:

FIGS. 1A, 1B, 1C, and 1D illustrate cross-sectional views of systems that include an IC device, a package substrate, and a base component having a surface, in accordance with various embodiments;

FIGS. 1E, 1F, and 1G illustrates plan views of the surface of FIGS. 1A-1D, in accordance with various embodiments;

FIG. 2A illustrates a plan view of a portion of the surface of FIGS. 1A-1D, the surface comprising via pads that contact associated interface pads, in accordance with various embodiments;

FIG. 2B illustrates a plan view of a portion of the surface of FIGS. 1A-1D, the surface comprising interface pads in a row and via pads, wherein particular via pads are offset from a center line the row and contact associated interface pads, in accordance with various embodiments;

FIG. 2C illustrates a plan view of a portion of the surface of FIGS. 1A-1D, the surface comprising via pads that ovderlap or intersect with interface pads, in accordance with various embodiments;

FIG. 2D illustrates a plan view of a portion of the surface of FIGS. 1A-1D, the surface comprising via pads that are spaced away from interface pads by a gap, in accordance with various embodiments;

FIG. 3A illustrates a plan view of a portion of the surface of FIGS. 1A-1D, the surface comprising interface pads in a column and via pads, in accordance with various embodiments;

FIG. 3B illustrates a plan view of a portion of the surface of FIGS. 1A-1D, the surface comprising interface pads in a column and via pads, wherein a via pad in row is offset from a center line the row and contacts an interface pad, in accordance with various embodiments;

FIG. 4A illustrates a plan view of a portion the surface of FIGS. 1A-1D, in accordance with some embodiments;

FIG. 4B illustrates a plan view of a portion of a layer of the base component of FIGS. 1A-1D and conductive vias terminating at or passing through the layer, in accordance with some embodiments;

FIG. 5A illustrates a plan view of a portion the surface of FIGS. 1A-1D, in which, in comparison with other examples described herein, selected via pads and conductive vias are omitted from regions where via pads and conductive vias could be located, in accordance with some embodiments;

FIG. 5B illustrates a plan view of a portion of a layer of the circuit board of FIGS. 1A-1D and conductive vias terminating at or passing through the layer, in accordance with some embodiments;

FIG. 6 illustrates a mobile computing platform and a data server machine employing one or more of the base components illustrated herein and/or one or more of the systems illustrated herein, in accordance with some embodiments; and

FIG. 7 is a functional block diagram of an electronic computing device employing one or more of the base components illustrated herein and/or one or more of the systems illustrated herein, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

Embodiments are directed to the field of fabricating microelectronic devices, wherein the microelectronic device may include IC devices (chips) and IC device packages communicatively connected to a base component, such as an interposer or a printed circuit board (PCB). A surface of the base component comprises a plurality of interconnect pads arranged in a regular pattern of rows and columns orthogonal to the rows. Individual interconnect pads in a row may be laterally offset from individual interconnect pads in an adjacent row. However, this is not essential. In some embodiments, interconnect pads in a row may be aligned with interconnect pads in adjacent rows, e.g., forming a square or rectangular pattern. In some embodiments, an IC device or package is coupled with the base component with a socket. The spatial pattern of the plurality of interconnect pads, pins, contacts, socket recesses, or other interconnect features on a base component (or socket) matches the spatial pattern of a plurality of interconnect features on the interface surface of an IC device or package, i.e., the pattern of interconnect features on one surface may be the mirror image of the pattern of interconnect features on the other surface. The plurality of interconnect pads (or pins or sockets) may be employed to conduct electrical signals between the IC device and the base component. Advantageously, the embodiments described herein do not require changes to the positions of the interconnect pads on an IC device or package. The embodiments described herein may compatible with the spatial pattern of interconnect features on the surface of an IC device, a package substrate, or an interposer.

Pairs of adjacent interconnect pads are coupled with pairs of interconnect features. Each pair of interconnect pads may be used for transmitting and receiving differential signals between the base component and an IC device, package substrate, or interposer. Each pair of adjacent interconnect pads is coupled with a signal via pad, which is coupled with a signal conductive via. Each pair of adjacent interconnect pads is shielded from crosstalk and other phenomena affecting signal integrity by multiple ground via pads and ground conductive vias tied to a ground reference voltage.

Advantageously, the embodiments described herein place via pads (and conductive vias coupled with via pads) used for differential and ground reference signals in locations that do not mirror the positions of the interconnect pads. Via pads (and conductive vias coupled with via pads) are placed in locations that may improve immunity to crosstalk and other phenomena affecting signal integrity.

A base component may include multiple layers between a top surface and a back surface. A pair of conductive traces may be provided in a layer of the base component. Placing conductive vias in locations described herein allows a pair of conductive traces to be routed in the layer on a path that may provide greater immunity to phenomena affecting signal integrity.

Conventionally, each of the plurality of interconnect pads on the interface surface of the base component is coupled with a via pad on the surface, and each via pad is coupled with a conductive via extending below the surface. In some embodiments, a via pad (and a conductive via coupled with the via pad) is not provided for an interconnect pad. Selected via pads and conductive vias may not be implemented in regions where via pads and conductive vias could be located, e.g., in regions where via pads and conductive vias are located in some embodiments. Advantageously, omitting a conductive via coupled with a via pad used to conduct a ground reference signal may allow a pair of conductive traces to be routed in the layer of the base component on a path that may provide greater immunity to phenomena affecting signal integrity.

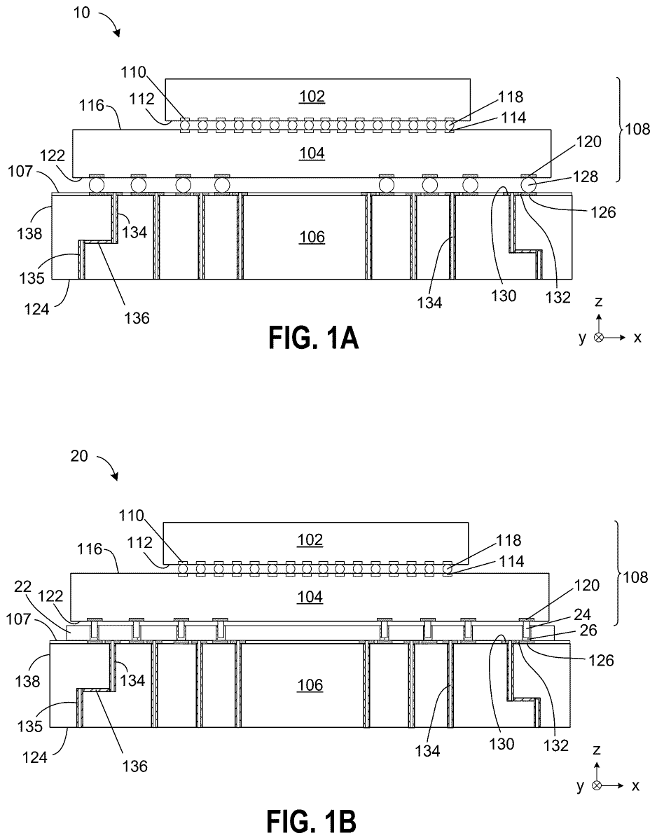

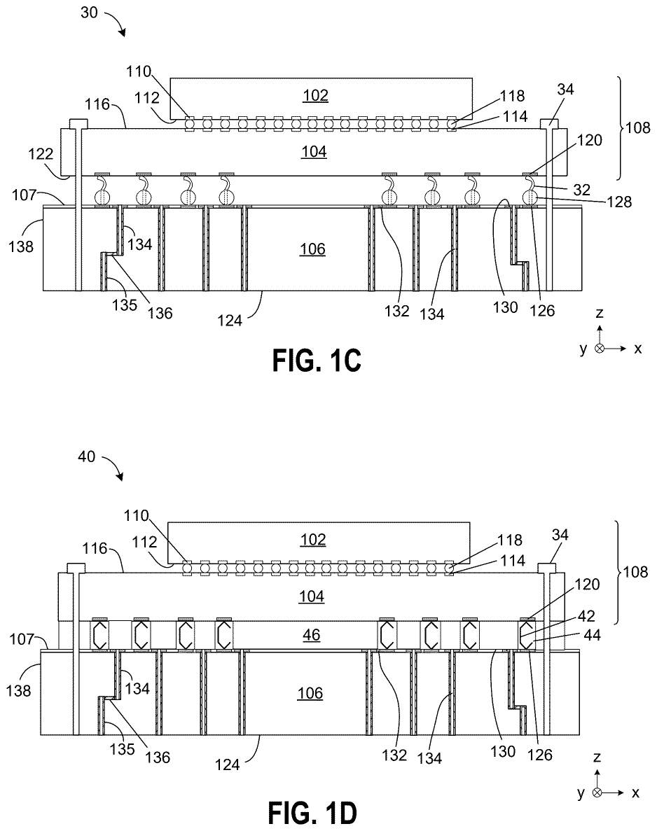

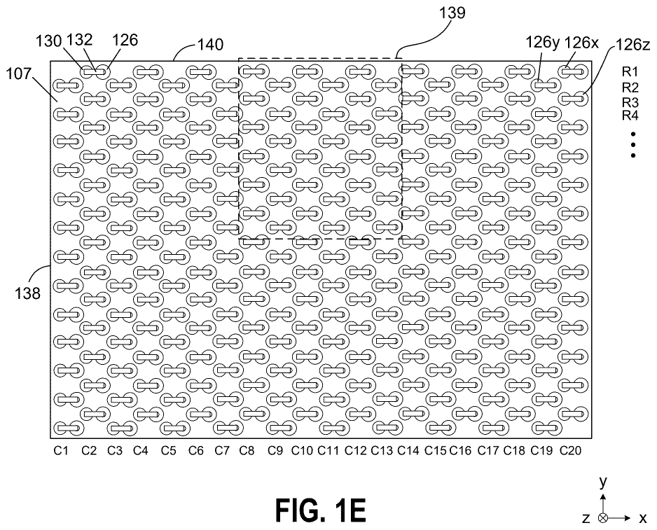

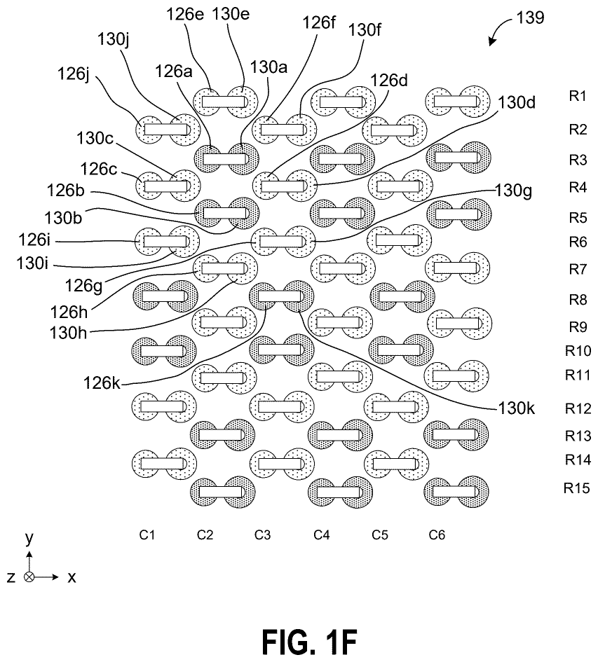

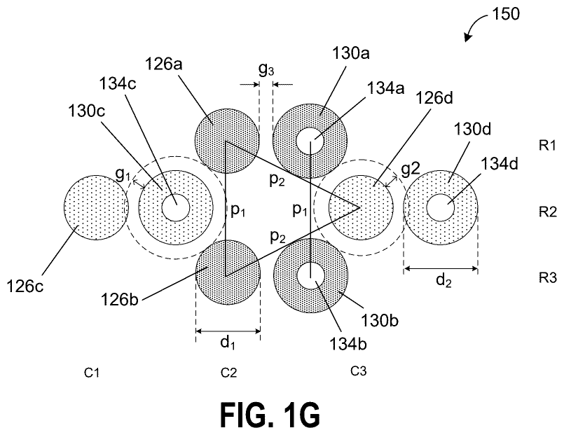

FIG. 1A illustrates a cross-sectional view of an example system 10 that includes an IC device 102, a package substrate 104, and a base component 106, e.g., a printed circuit board, the base component having a top surface 107, in accordance with various embodiments. FIG. 1E illustrates a plan view of the top surface 107, in accordance with an example. FIGS. 1A-1E illustrate examples of electrical communication routes between a microelectronic device and a base component. In the illustrated examples, IC device 102 is electrically coupled to base component 106 by package substrate 104. In addition, while only a single IC device 102 is shown in the example, in other examples multiple IC devices may be coupled with package substrate 104.

The IC device 102 may be packaged in any manner known in the art. In one example, an IC device package 108 includes IC device 102 and package substrate 104. In other examples, an IC device package 108 includes IC device 102 and one or more IC dies or components coupled with package substrate 104. The IC dies may be any IC die, chiplet, or photonic IC die comprising circuitry for processing, routing, or storing data. In some examples, an IC device package 108 includes active or passive components, such as inductors, capacitors, and heat sinks. In some examples, IC device package 108 is electrically coupled to base component 106.

In the illustrated example, IC device 102 comprises conductive features 110 on a surface 112. The IC device 102 may be any suitable device, such as one or more processor units (e.g., system-on-a-chip (SoC), processor core, graphics processor unit (GPU), accelerator, chipset processor), Input/Output (I/O) controllers, or memory controller, or network interface controller. IC device 102 may be a photonic IC device. In some embodiments, IC device 102 comprises memory circuitry, e.g., DRAM, SRAM, flash memory, or high bandwidth memory (HBM). In some embodiments, the IC device 102 comprises one or more additional components, such as active or passive devices, e.g., capacitors, decoupling capacitors, resistors, inductors, fuses, diodes, transformers, sensors, and electrostatic discharge (ESD) devices.

Package substrate 104 comprises conductive features 114 on a surface 116 facing surface 112 of IC device 102. In the illustrated example, the IC device 102 is mechanically attached and electrically coupled to package substrate 104 through a plurality of solder features 118 between conductive features 110 and conductive features 114. In some alternatives, the IC device 102 is mechanically attached and electrically coupled to package substrate 104 using hybrid bonding techniques. (In hybrid bonding, oxide portions of surfaces 112, 116 may be bonded together with Vander der Waals forces, while metallurgical bonds are formed between conductive features on surfaces 112, 116 using high temperature processing.)

The package substrate 104 may be any suitable substrate with (or without) a core. Package substrate 104 may comprise organic or inorganic materials, or a combination of organic and inorganic materials. In some examples, the package substrate 104 comprises a glass core. In some embodiments, the package substrate 104 includes a core with a redistribution layer (RDL) on one or both sides of the core. In some examples, the package substrate 104 is an interposer. In some examples, the package substrate 104 comprises an embedded bridge or other device comprising electrical circuitry, such as power supply circuitry. In some examples, the package substrate 104 comprises embedded components, such as, inductors or capacitors. The package substrate 104 also includes conductive features 120 on a surface 122, which is opposite surface 116.

Embodiments comprise any suitable base component 106. In some embodiments, the base component 106 is a printed circuit board (PCB). Base component 106 has a back surface 124, which is opposite top surface 107. In the example illustrated in FIG. 1A, top surface 107 faces surface 122 of the package substrate 104. Base component 106 has sidewalls, including sidewall 138 and sidewall 140. As illustrated, sidewall 140 is orthogonal to sidewall 138. Base component 106 may include multiple layers. In various examples, base component 106 has 4-22 layers of conductive material, e.g., copper layers separated by layers of epoxy glass fiber or other dielectric material.

Base component 106 has a plurality of interface pads 126 at top surface 107. In the example illustrated in FIG. 1A, the package substrate 104 is mechanically attached and electrically coupled to base component 106 through a plurality of solder features 128 between conductive features 120 and interface pads 126.

In some embodiments, an IC device or package is coupled with an IC base board using a socket. FIG. 1B illustrates a cross-sectional view of an example system 20 that includes the IC device 102, package substrate 104, base component 106, and a socket 22 in accordance with various embodiments. In the example illustrated in FIG. 1B, socket 22 is on or attached to surface 107 of base component 106. Interconnect pins 24 on surface 122 of package substrate 104 are inserted in conductive recesses 26 of socket 22. In some alternatives, the shown configuration may be reversed, e.g., recesses may be provided on surface 122 and interconnect pins may be provided on surface 107.

In some embodiments, an IC device or an IC package may be coupled with an IC base board using pliant, bendable, or compressible pins. FIG. 1C illustrates a cross-sectional view of an example system 30 that includes the IC device 102, package substrate 104, base component 106, and pins 32 in accordance with various embodiments. In the example illustrated in FIG. 1C, pins 32 include a cantilevered portions at one end that contact conductive features 120 on surface 122 of package substrate 104, and a second portion and the other end which is attached to and coupled with interface pads 126 at top surface 107 by solder balls 128. The tips of the cantilevered pins 32 may be held in compression contact with the conductive features 120 by any suitable retention mechanism, such as screws 34.

FIG. 1D illustrates a cross-sectional view of another example system 40 that includes the IC device 102, package substrate 104, base component 106, and pliant, bendable, or compressible pins 42 in accordance with various embodiments. In the example illustrated in FIG. 1D, compressible pins 42 are seated within recesses 44 of a socket-like mechanism 46. Compressible pins 42 may be in a shape resembling the letter C (as shown) or the letter G, or any other suitable shape. One end of each pin 42 contacts a conductive feature 120 while the other end contacts an interface pad 126. Pins 42 may be held in compression contact with the conductive features 120 and interface pads 126 by any suitable retention mechanism, such as screws 34.

As illustrated in FIG. 1E, the interface pads 126 are arranged in a regular pattern of rows (R1, R2, R3, . . . ) and columns (C1, C2, C3, . . . ) orthogonal to the rows. In the example illustrated in FIG. 1E, individual interface pads 126 in a row are laterally offset from individual interconnects in an adjacent row. For example, interface pad 126x in row R1 is laterally offset from interface pad 126y in adjacent row R2. Interface pad 126x in row R1 is aligned with and vertically offset from interface pad 126z in row R3, which is adjacent to row R2. However, the arrangement shown in FIG. 1E is not essential. In some embodiments, interconnect pads in a row are not laterally offset with interconnect pads in an adjacent row. For example, interconnect pad 126x may be vertically aligned with both interconnect pads 126y, 126z.

The pattern of interface pads 126 on surface 107 of base component 106 matches a pattern of conductive features on a surface of another device, e.g., the pattern of features on surface 107 is a mirror image of the pattern of features on surface 122. Similarly, the pattern of recesses in a socket may be a mirror image of the pin field on the device or devices to be mated with the socket. In some examples, the pinout pattern of conductive features 110 on surface 112 of IC device 102 are arranged in the same pattern as that of interface pads 126 on surface 107. In some examples, the pinout pattern of conductive features 120 on a surface 122 of package substrate 104 are arranged in the same pattern as that of interface pads 126 on surface 107.

As illustrated in FIGS. 1A through 1E, each interface pad 126 is associated with a via pad 130. A via pad 130 is adjacent and/or proximate the interface pad 126 with which it is associated, and the two pads are electrically coupled by a conductive trace 132 (in the example of FIG. 1E). In the example illustrated in FIG. 1E, each via pad 130 is in the same row as, and aligned with, the interface pad 126 with which it is coupled, e.g., a centerline (not depicted) of a row would pass through the centers of via pad 130 and interface pad 126 that are in the same row. The conductive traces 132 extend in the same direction as the row. The conductive traces 132 may be metal features flush with the surface 107 or solder features on surface 107. The interface pad 126, via pad 130, and conductive trace 132 together form a shape resembling a “dog bone.” As illustrated, the via pads 130 are arranged in a pattern that is the same as or similar to the pattern of the interface pads 126.

Base component 106 includes multiple conductive vias 134 extending below the surface 107. A conductive via 134 may be integral or coupled with one of the via pads 130 at surface 107. Each conductive via 134 may be coupled with one of the via pads 130. Via pads are depicted herein (in plan views) as a circle enclosing a smaller circle (see FIG. 1G, for example). The inner, smaller circles represent a conductive via coupled with the via pad. A conductive via 134 may extend either from the top surface 107 to the back surface 124, or from one of the surfaces to a layer between the surfaces. A conductive via 134 in a layer may be under the via pad with which it is connected, such that the conductive via 134 is within a footprint of the via pad. Conductive vias 134 may be any suitable type of via, such as a plated through hole or a blind via, with or without conductive or dielectric fill. Base component 106 may have conductive traces or planes 136 in one more or more of the layers and conductive via 134 may extend from the top surface 107 to contact one of the conductive traces or planes 136. A conductive via 135 may extend from one of the conductive traces or planes 136 and may not be within a footprint of a via pad. (Examples herein include conductive vias 134 in a layer that are in substantially the same position as a via pad with which the via is connected with at top surface 107; these examples refer to conductive vias 134, not conductive vias 135, which are not within the footprint of a via pad.) Although the interface pads 126 and via pads 130 in FIG. 1E are shown as being circular, this is not essential. In some examples, the interface pads 126 and via pads 130 are any suitable non-circular shape, such as oblong, oval, square.

Conductive features 110, 114, and 120, interface pads 126, via pads 130, conductive vias 134, 135, interconnect pins 24, conductive recesses 26, pins 32, compressible pins 42, recesses 44, and any other features used to conduct an electrical signal may be composed of any conductive material, including but not limited to metals, such as copper and aluminum, and alloys thereof. Base component 106 may be primarily composed of an appropriate material, including, but not limited to, bismaleimine triazine resin, fire retardant grade 4 material, polyimide materials, glass reinforced epoxy matrix material, and the like, as well as laminates or multiple layers thereof.

The pinfield illustrated in FIG. 1E may include various signaling interfaces and power domains in close proximity. High-speed digital signals are generally transmitted and received using a pair of differential signals. Each signal in the pair of differential signals requires its own interconnect features, e.g., pad and conductive trace. A first interconnect of the pair conducts a positive polarity and a second interconnect of the pair conducts a negative polarity. It is desirable to keep the respective interconnect features of pair of differential signals close together so that phenomena that disturbs one signal of the pair disturbs the other signal to by approximately the same amount. Consequently, the overall differential disturbance received by a closely coupled differential signal pair is reduced in comparison to differential signal pairs less closely coupled. In addition, it is desirable to provide metal features charged to a reference voltage, e.g., ground, Vss, surrounding a pair of differential signal interconnects to isolate the pair.

FIG. 1F is a plan view illustrating a portion 139 of top surface 107 at an enlarged scale, in accordance with various embodiments. The example of FIG. 1F includes interface pads 126a, 126b, 126c, 126d, 126e, 126f, 126g, 126h, 126i, 126j, and 126k. In addition, the example of FIG. 1F includes via pads 130a, 130b, 130c, 130d, 130e, 130f, 130g, 130h, 130i, 130j, and 130k. Each via pad may be coupled with a conductive via. As illustrated in FIG. 1F, some features may be used for conducting a pair of differential signals. For example, interface pads 126a, 126b (“signal interface pads”) and their associated via pads 130a, 130b (“signal via pads”) (and conductive vias 134 (“signal vias”)) may be used for conducting a pair of differential signals. Some features may be used for a reference voltage. For example, interface pads 126c-126j (“ground interface pads”) are designated to conduct a ground reference signal. Similarly, via pads 130c-130j (“ground via pads”) (and conductive vias 134 (“ground vias”)) may be used to conduct a reference voltage. As one example, ground via pads 130c, 130d may be used to conduct a ground reference signal. As illustrated in the example, signal interface pads 126a, 126b and their associated signal via pads 130a, 130b are close to one another. Signal interface pads 126a, 126b are in the same column and are separated in the row direction by one row. As also illustrated in the example, ground interface pads are near to and surround the pair of signal interface pads 126a, 126b. (Column numbering in FIGS. 1F and 1G differs from FIG. 1E for ease of reference. FIG. 1F includes columns C1, C2, C3, C4, C5, and C6, and rows R1, R2, R3, R4, R5, R6, R7, R8, R9, R10, R11, R12, R13, R14, and R15.)

FIG. 1G is an enlarged view a group of features 150 at surface 107 that includes a pair of signal interface pads and their associated signal via pads in a first and third row, and two ground interface pads and their associated ground via pads in a third row between the first and second rows. Specifically, group of features 150 includes interface pads 126a, 126b, 126c, and 126d, and via pads 130a, 130b, 130c, and 130d. Also illustrated are the parts of conductive vias 134a, 134b, 134c, and 134d present or proximate surface 107. (As noted, via pads are depicted herein as a circle enclosing a smaller circle representing a conductive via coupled with the via pad.) For clarity of illustration, conductive traces 132 between interface pads 126 and associated via pads 130 are omitted. In an example, a manufacturing process requires a clearance g1 around via pads used for a ground signal, e.g., via pad 130c, and a clearance g2 of around interface pads 126 used for a ground signal, e.g., interface pad 126d. Clearances g1 and g2 vary depending on the manufacturing process. A distance g3 separates interface pad 126 and an associated via pad 130 used for a differential signal, e.g., interface pad 126a and a via pad 130a. While distance g3 may vary depending on the manufacturing process, one example value of g3 is approximately 2.6 mils (0.0026 inches). Conductive traces 132 are at least the distance g3 in length. In various embodiments, interface pads 126 have a diameter d1 of approximately 15.5 mils and via pads 130 have a diameter d2 of approximately 18 mils. These values are examples and diameters d1 and d2 may vary depending on the manufacturing process or a design choice. A pair of interface pads 126 used for differential signals may be separated by a pitch p1. The pair of via pads 130 used for differential signals are also separated by the pitch p1. Each pad of the pair of interface pads 126 are separated from the nearest via pads 130 in an adjacent row by a pitch p2, which may be larger than pitch p1.

To reduce crosstalk, more ground isolation pins could be added or the pitch between pairs of signal features could be increased. However, either option would reduce I/O bandwidth density and/or increase LGA/BGA pin count. Either option may increase package form factor and/or product costs. Advantageously, embodiments described herein may reduce crosstalk without additional ground isolation pins and without increasing the pitch between pairs of signal features.

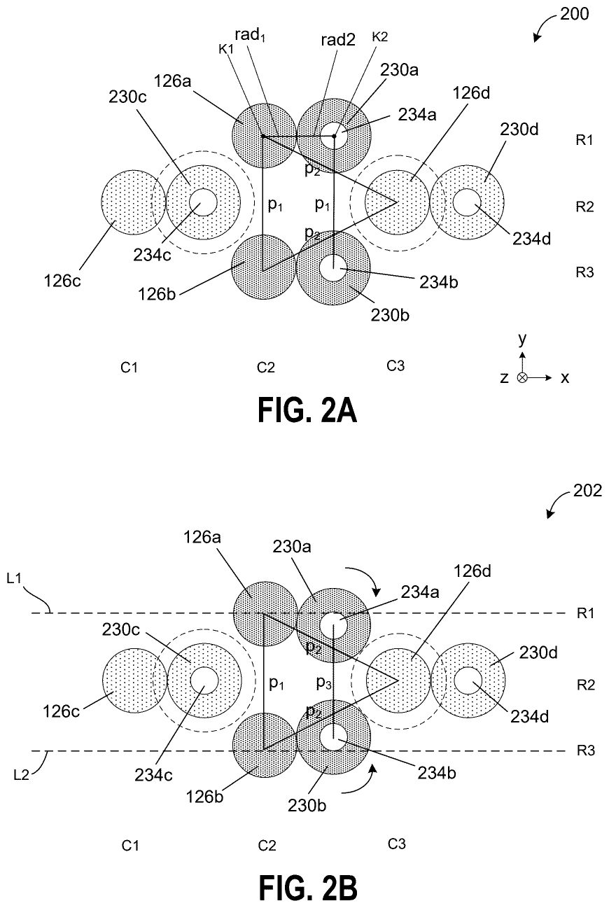

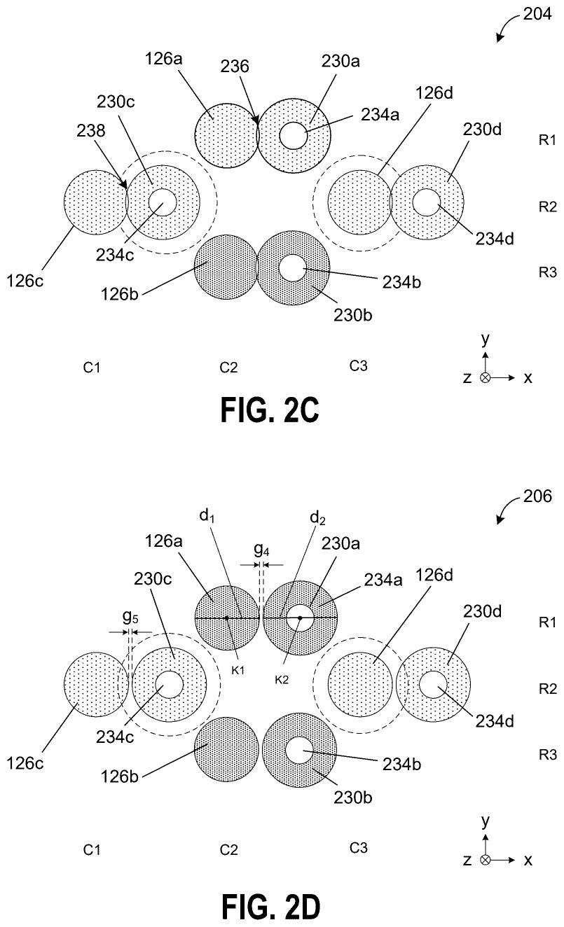

FIG. 2A illustrates a plan view of a portion of a surface of an apparatus comprising via pads that contact interface pads in accordance with some embodiments. In some examples, the apparatus is base component 106 and the surface is a top surface 107. FIG. 2A illustrates a group 200 of a group of features at the surface that includes a pair of signal interface pads and their associated signal via pads in a first and third row, and two ground interface pads and their associated ground via pads in a third row between the first and second rows. Specifically, the group 200 includes interface pads 126a, 126b, 126c, and 126d, and via pads 230a, 230b, 230c, and 230d. Interface pads 126a, 126b, 126c, and 126d in group 200 may be located in the same positions as they are in group 150 of FIGS. 1E-1G. However, the positions of via pads 230a, 230b, 230c, and 230d of group 200 differs from the positions of via pads 130a, 130b, 130c, and 130d of FIGS. 1E-1G.

As illustrated in FIG. 2A, first and second interconnect pads 126a, 126b are in first and second rows (R1, R3) in a first column (C2). The first and second interconnect pads are signal interface pads for coupling with a pair of differential signals. A first via pad 230a in the first row contacts the first interconnect pad 126a and a second via pad 230b in the second row contacts the second interconnect pad 126b. In comparison to group 150, the first via pad 230a of group 200 is shifted laterally in the row direction (x-axis) until its perimeter is in contact with interface pad 126a. Similarly, the second via pad 230b is shifted laterally until its perimeter is in contact with interface pad 126b. In this example, the position of the first and second via pads 230a, 230b in the column direction (y-axis) does not change. As illustrated, conductive vias 234a, 234b are shifted laterally in a direction and distance to maintain their respective positions with respect to the first and second via pads 230a, 230b, e.g., a via pad centered on a conductive via may remain centered on the conductive via after the lateral shift of the via pad. Via pads 230a, 230b and interface pads 126a and 126b are both separated by the same pitch p1. In comparison to group 150, solder features 128 between via pads 230a, 230b and interface pads 126a, 126b may be omitted in group 200. Solder features 128 may not be required because contact between an interface pad and a via pad provides electrical conductivity. However, the omission of solder features is not essential and, in some embodiments, a solder feature may be applied over an interface pad and an associated via pad contacting or intersecting the interface pad.

As illustrated in FIG. 2A, a via pad comprises a perimeter in contact with an adjacent or associated interconnect pad. Whether a via pad “contacts” an interconnect pad may be determined with reference to any suitable geometric parameter. As one example, the radius of a via pad or an interconnect pad extends between a center of the pad and a perimeter of the pad. As illustrated, via pad 230a comprises a first radius rad2 and a center K2, and interconnect pad 126a comprises a second radius rad1 and a center K1. In some embodiments, a distance between a center of a via pad and a center of an interconnect pad is approximately equal to a sum of their respective first and second radii. For example, a distance between a center K2 of the via pad 230a and a center K1 of the interconnect pad 126a is approximately equal to a sum of the radii of the two pads (rad1+rad2).

Still referring to FIG. 2A, third and fourth interconnect pads 126c, 126d are in a third row (R2) between the first and second row and second rows (R1, R3). Third interconnect pad (126d) is in a second column (C3) adjacent to the first column (C2), and the fourth interconnect pad (126c) is in a third column (C1) adjacent to the first column (C2). The third and fourth interconnect pads 126c, 126d are ground interface pads for coupling with a reference voltage. A third via pad 230d in the third row (R2) contacts the third interconnect pad 126d. In the illustrated example, the third via pad 230d is aligned with a center line (not shown) of the third row (R2). The third via pad 230d comprises a perimeter in contact with the third interconnect pad 126d. A fourth via pad 230c in the third row (R2) contacts the fourth interconnect pad 126c. In the illustrated example, the fourth via pad 230c is aligned with a center line (not shown) of the third row (R2). The fourth via pad 230c comprises a perimeter in contact with fourth interconnect pad 126c. As illustrated, conductive vias 234c, 234d are shifted laterally in a direction and distance to maintain their respective positions with respect to the third and fourth via pads 230c, 230d. In comparison to group 150, solder features 128 between via pads 230d, 230c and interface pads 126d, 126c are omitted in the illustration of group 200. However, the omission of solder features is not essential and, in some embodiments, solder features may be provided.

While a center line of the third row (R2) is not depicted in FIG. 2A, it should be understood that the center line of a row may be a line parallel to and bisecting the interconnect pads 126 in the row.

FIG. 2C illustrates a plan view of the portion of the surface depicted in FIG. 2A, in accordance with some alternative embodiments. As illustrated, group 204 includes via pads 230a, 230b that may intersect or partially overlap with interface pads 126a, 126b. In some embodiment, a via pad may intersect or partially overlap with an interface pad by an overlap portion 236. In some embodiments, up to five percent (5%) of the area of a via pad, e.g., 230a, 230b, may intersect or partially overlap (in plan view) with an interface pad. Similarly, in some examples, the third via pad 230d and fourth via pad 230c may intersect or partially overlap with interface pads 126d, 126c by an overlap portion 238. In some embodiments, up to five percent (5%) of the area of a via pad, e.g., 230c, 230d, (in plan view) may intersect or partially overlap with an interface pad. In some embodiment, a via pad may intersect or partially overlap with an interface pad by up to twenty five percent (25%) of the area of a via pad.

FIG. 2D illustrates a plan view of the portion of the surface depicted in FIG. 2A, in accordance with some alternative embodiments. As illustrated, group 206 includes via pads 230a, 230b that are spaced away from interface pads 126a, 126b by a gap g4. The gap g4 is at the closest point between a via pad and an interface pad. In some embodiments, the gap g4 is less than eight percent (8%) of the diameter of d1 of an interface pad 126. In some embodiments, the gap g4 is less than eight percent (8%) of the diameter of d2 of a via pad 234. In various embodiments, the gap g4 may be less than 1.44 mils, less than 1.24 mils, or less than 1.0 mils. (1.0 mils equals 0.001 inches.) Similarly, in some embodiments, the third via pad 230d and fourth via pad 230c may be spaced away from interface pads 126d, 126c by a gap g5. The gap g5 is at the closest point between a via pad and a interface pad. In some embodiments, the gap g5 is less than eight percent (8%) of the diameter of d1 of an interface pad 126. In some embodiments, the gap g5 is less than eight percent (8%) of the diameter of d2 of a via pad 234. In various embodiments, the gap g5 may be less than 1.44 mils, less than 1.24 mils, or less than 1.0 mils. In some embodiments, the gaps g4 and g5 may be less than four percent (4%) of diameter d1 or d2. In some embodiments, the gaps g4 and g5 may be less than ten percent (10%) of diameter d1 or d2. Still referring to FIG. 2D, via pad 230a comprises a first radius (½ of d2) and a center K2, and interface pad 126a comprises a second radius (½ of d1) and a center K1. In some embodiments, a distance between a center of a via pad and a center of an interconnect pad is greater than a sum of the radii of the via pad and the interconnect pad. The amount by which the distance between the centers is greater than the sum of the radii is approximately equal to the gap g4 (via pad radius+interconnect pad radius+gap g4=distance). While solder features are not depicted in FIG. 2D, solder features may be provided for electrical conductivity.

FIG. 2B illustrates a plan view of a portion of a surface of an apparatus comprising interface pads in a row and via pads offset from a center line the row that intersect with the interface pads in accordance with some embodiments. In some examples, the apparatus is base component 106 and the surface is a top surface 107. FIG. 2B illustrates a group 202 of a group of features at the surface that includes a pair of signal interface pads and their associated signal via pads in a first and third row, and two ground interface pads and their associated ground via pads in a third row between the first and second rows. The group 202 includes the same features depicted in group 200 in FIG. 2A. Interface pads 126a, 126b, 126c, and 126d in group 200 may be located in the same positional arrangement as they are in group 150 of FIGS. 1E-1G. In addition, the third via pad 230d and fourth via pad 230c may be located in the same positional arrangement as they are in any of the groups 200, 204, or 206. However, in group 202, first via pad 230a and second via pad 230b (and their associated conductive vias 234a, 234b) are in rotated from their positions in groups 200, 204, and 206. As with groups 200 and 204 solder features 128 may be omitted in group 202. While solder features are not depicted in FIG. 2B, solder features may be provided for electrical conductivity.

In comparison with FIG. 2A, the position of via pad 230a (and conductive via 234a) is rotated downward and clockwise in FIG. 2B as illustrated by an arrow. In comparison with FIG. 2A, the position of via pad 230b (and conductive via 234b) is rotated upward and counter clockwise in FIG. 2B as illustrated by an arrow. As illustrated in FIG. 2B, a center of the first via pad 230a is offset from a center line L1 of the first row R1 in a first direction, and a center of the second via pad 230b is offset from a center line L2 of the second row in a second direction different from the first direction. In an example, the second direction is opposite the first direction. A consequence of the positional shift is that a first pitch P1 between the first and second interconnect pads 126a, 126b is different than a second pitch P3 between the first and second via pads 230a, 230b. The first pitch P1 may be greater than the second pitch P3. In an example, first pitch P1 is 33 mils and the second pitch P2 is 27.6 mils. Accordingly, the distance between signal via pads 230a, 230b used for a pair of differential signals may be reduced by 5.4 mils as compared with the signal via pads 130 a, 130 b depicted in FIG. 1G. Advantageously, the reduced distance between signal via pads 230a, 230b increases the immunity of a pair differential signals to crosstalk. In addition, the reduced distance between signal via pads 230a, 230b also increases the distance between diagonal pairs of signal via pads, further reducing crosstalk.

The compressed intra-pair pitch between signal vias illustrated in FIG. 2B may reduce crosstalk for both traces-to-via and via-to-via crosstalk coupling. The compression also increases the distance between diagonal via pairs, which may further mitigate crosstalk. Moreover, the overall void size between the differential signals shrinks after the compression, which reduces the field leakage through the ground plane and consequently reduces the inter-pair trace-to-trace coupling.

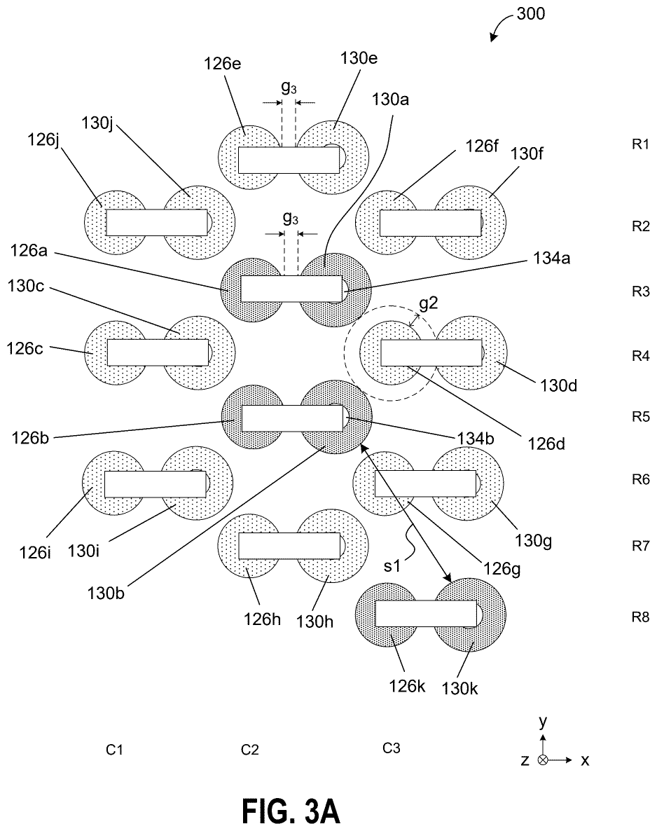

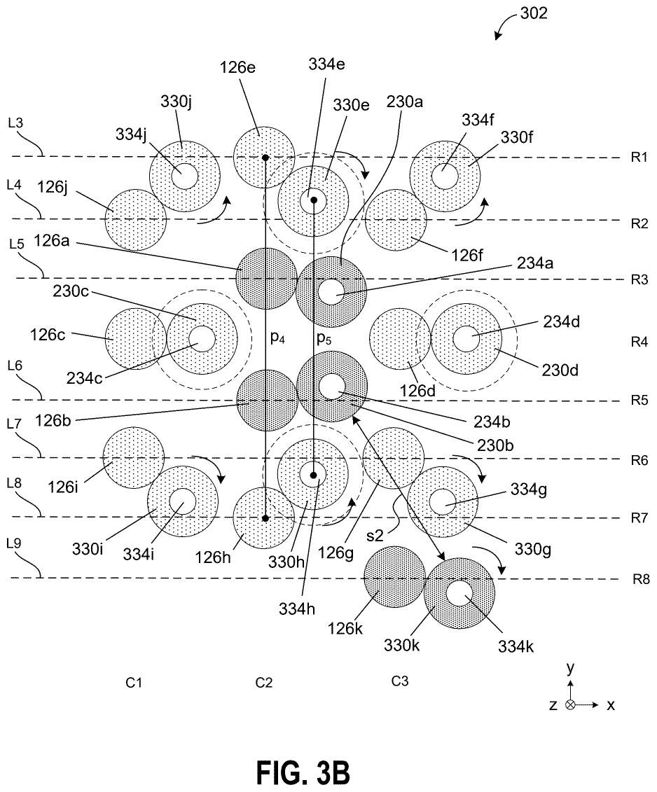

In FIG. 2B, the via pads comprises a perimeter in contact with an adjacent or associated interconnect pad. It should be appreciated that in some embodiments, a via pad in any of the positions depicted in FIG. 2B (or in FIG. 3B) may intersect or partially overlap with an interface pad by an overlap portion as illustrated in FIG. 2C. In addition, it should be appreciated that in some embodiments, a via pad in any of the positions depicted in FIG. 2B (or in FIG. 3B) may be spaced away from an interface pad by a gap g4, as illustrated in FIG. 2D.

FIGS. 3A-3B illustrate plan views of a portion of a surface of an apparatus in accordance with some embodiments. In some examples, the apparatus is base component 106 and the surface is a top surface 107. The example of FIG. 3A includes a group 300 comprising interface pads 126a-126k, associated via pads 130a-130k, and conductive vias, which may be in the same positions as described with reference to FIGS. 1A-1G . (Column and row numbering in FIGS. 3A and 3B may differ from other figures for ease of reference. FIGS. 3A and 3B includes rows R1, R2, R3, R4, R5, R6, R7, and R8, and columns C1, C2, and C3.)

FIG. 3B illustrates a group 302 comprising interface pads in a row and via pads offset from a center line the row, wherein the via pads intersect with the interface pads in accordance with some embodiments. In the example of FIG. 3B, interface pads 126a-126k may be in the same positions as described with reference to FIGS. 1A-1G . Via pads 230a, 230b, 230c, and 230d, and conductive vias 234a, 234b, 234c, and 234d may be in the same positions as described with reference to FIG. 2B.

The example of FIG. 3B also includes via pads 330e, 330f, 330g, 330h, 330i, 330j, and 330k. In comparison to group 300 of FIG. 3A, the via pads 330e, 330f, 330g, 330h, 330i, 330j, and 330k of group 302 are shifted laterally in the row direction (x-axis) until their respective perimeters contact and/or intersect with interface pads 126e, 126f, 126g, 126h, 126i, 126j, and 126k. In addition, in comparison to group 300, via pads 330e, 330f, 330g, 330h, 330i, 330j, and 330k are rotated downward and clockwise, or rotated upward and counter clockwise, in FIG. 2B as illustrated by the arrows in the figure. Specifically, centers of via pads 330e, 330i, 330g, and 330k are offset from respective row center lines L3, L7, and L9 in a first direction, and centers of via pads 330j, 330f, and 330h are offset from respective row center lines L4 and L8 in a second direction different from the first direction. In an example, the second direction opposite the first direction.

In the example of FIG. 3B, the respective positions of conductive vias 134 at the centers of via pads 130e, 130f, 130g, 130h, 130i, 130j, and 130k also shift from their positions in FIG. 3A to positions in which they remain under their associate via pad at its new location. More specifically, conductive vias 334e, 334f, 334g, 334h, 334i, 334j, and 334k are shifted laterally and rotated so as to maintain their respective positions with respect to via pads 330e, 330f, 330g, 330h, 330i, 330j, and 330k.

In the illustrated example, interconnect pads 126a and 126b may be used for coupling with a pair of differential signals. Interconnect pads 126a and 126b are in column C2, and in rows R3 and R5, respectively. In addition, interconnect pads 126e and 126h may be used for coupling with a reference voltage. Interconnect pads 126e and 126h are in the same column C2 as interconnect pads 126a and 126b.

Interconnect pad 126e is in row R1 that is separated from the row R3 in which the interconnect pad 126a is located by one row, i.e., interconnect pad 126e is separated from the interconnect pad 126a by row R2. Via pad 330e intersects with the interconnect pad 126e and is vertically offset from a center line of row R1. Interconnect pad 126h is in row R7 that is separated from the row R5 by one row, i.e., interconnect pad 126h is separated from the interconnect pad 126b by row R6. Via pad 330h intersects with the interconnect pad 126h and is vertically offset from a center line of row R7.

In the illustrated example, the distance between the third and fourth interconnect pads 126e, 126h is a pitch P4. The distance between the third and fourth via pads 330e, 330h is a pitch P5. In various embodiments, the pitch P4 is greater than the pitch P5.

A consequence of the positional shifts of ground via pads 330e and 330h is that these ground via pads are closer to signal via pads 230a, 230b. The positional shifts of ground via pads 330e and 330h “dedicates” them to signal via pads 230a, 230b. Differential signal via pairs with dedicated ground via protection may have improved immunity to crosstalk in comparison to differential signal via pairs without dedicated ground via protection. At the same time, the positional shifts of ground via pads 330j, 330k, 330i, and 330g results in these ground via pads being further from signal via pads 230a, 230b.

As illustrated in FIG. 3B, the distance between a signal pad in a pair of signal interface pads in group 302 and a diagonally adjacent signal pad in another pair of signal interface pads is increased in comparison to group 300 of FIG. A. For example, signal via pads 130a, 130b are used for a pair of differential signals and signal via pad 130k along with another signal via pad (not depicted in FIG. 3A) is used for another pair of differential signals. A distance s1 separates signal via pad 130b from signal via pad 130k. Signal via pad 130b may be said to be “diagonally adjacent” to signal via pad 130k. In arrangement 302, signal via pads 230a, 230b are used for a pair of differential signals and signal via pad 330k along with another signal via pad (not depicted in FIG. 3B) is used for another pair of differential signals. A distance s2 separates signal via pad 230b from signal via pad 330k. In various embodiments, the distance s2 is greater than the distance s1, which may advantageously reduce crosstalk between a signal pad of one pair and a diagonally adjacent signal via pad of another pair.

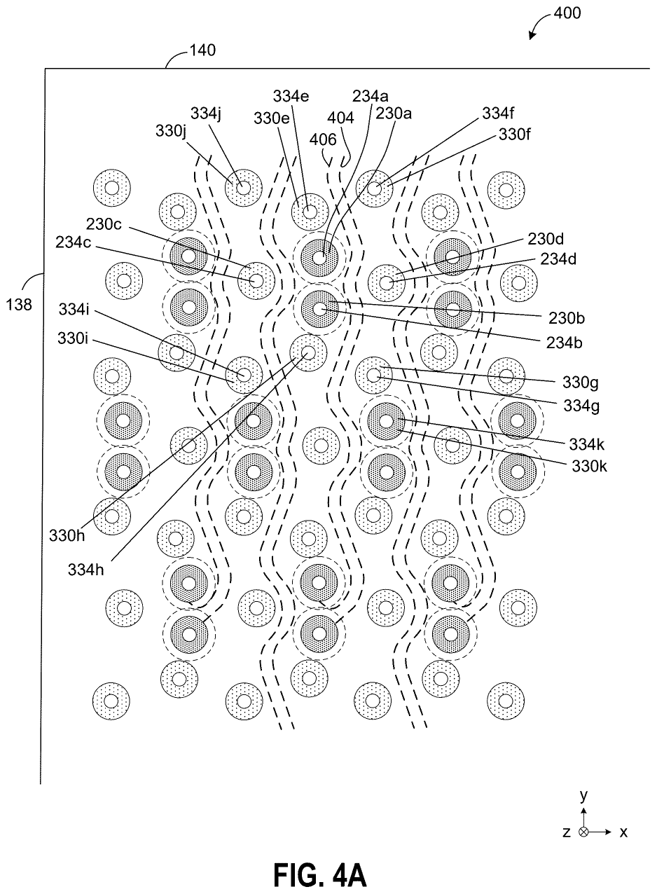

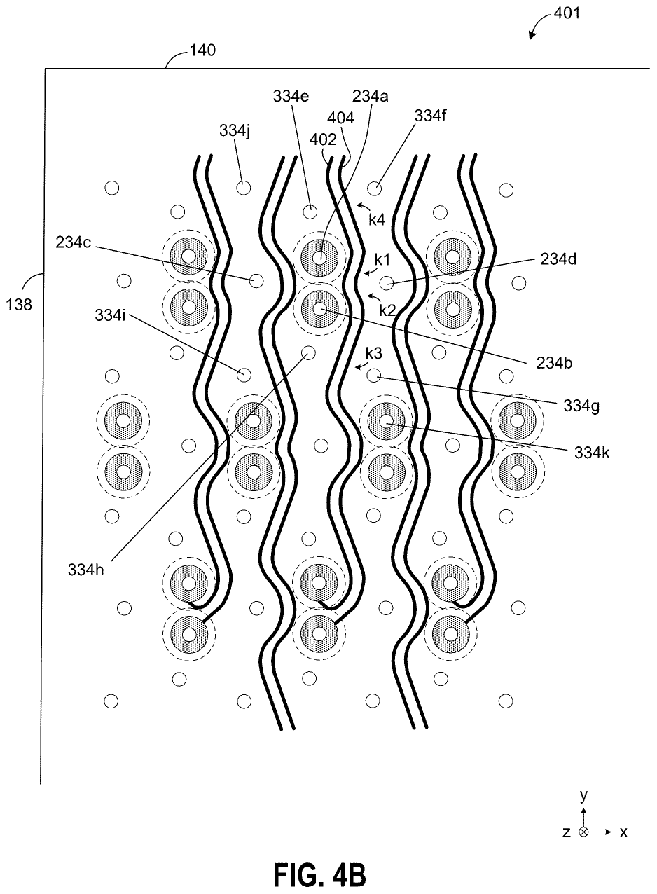

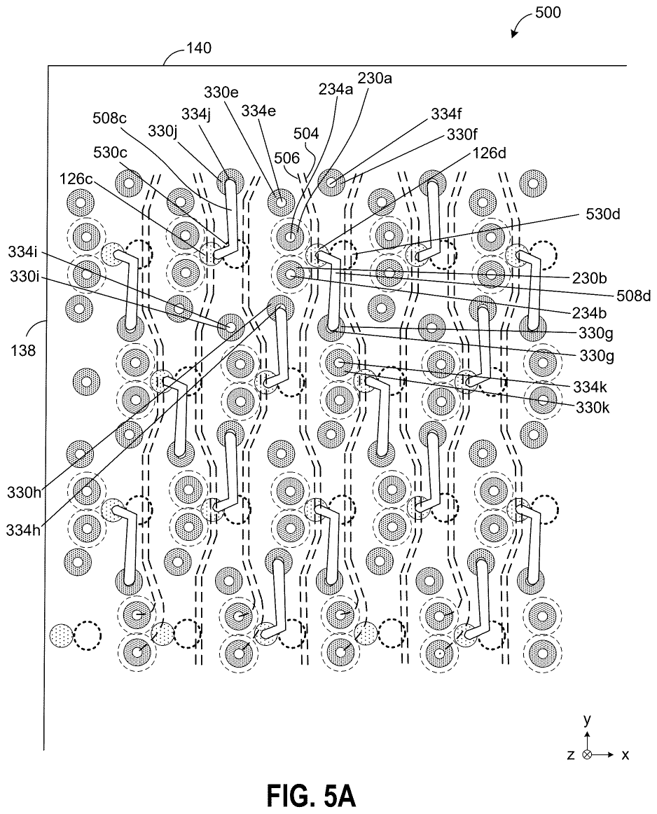

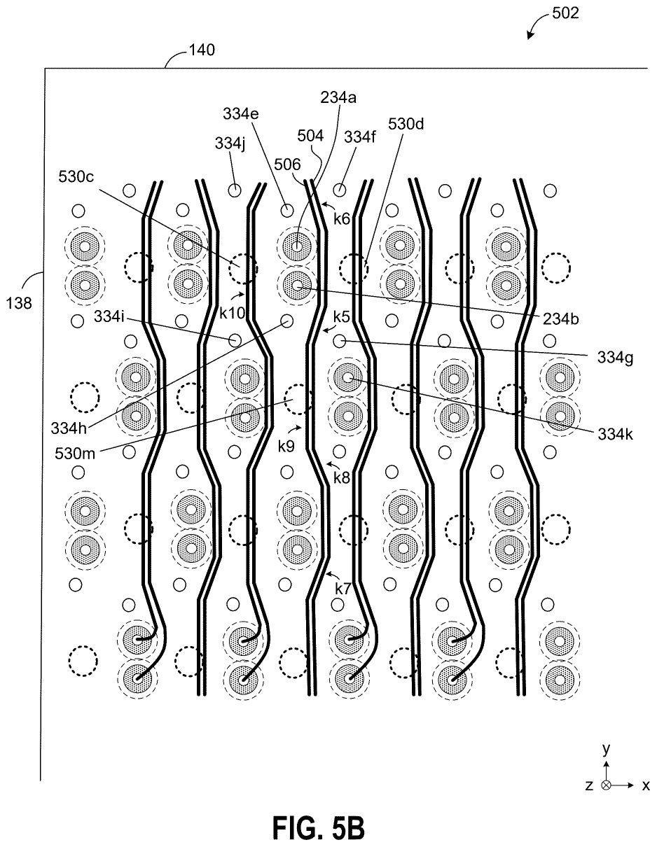

As described above, base component 106 has a plurality of layers of conductive material. Each of the signal and ground via pads at top surface 107 may be coupled with a conductive via that extends below the surface. In various embodiments, a conductive via coupled with a via pad at top surface 107 extends from the via pad to a point below the surface at or through any of the layers of base component 106. In various embodiments, a conductive via may extend below the position of the via pad with which it is coupled at top surface 107, as shown in FIG. 3B. Examples illustrating the positional arrangement of conductive vias and conductive traces in a layer of base component 106 are presented with reference to FIGS. 4A-4B and FIGS. 5A-5B.

FIG. 4A illustrates a plan view of a portion 400 of a surface of an apparatus in accordance with some embodiments. In some examples, the apparatus is base component 106 and the surface is a top surface 107. Portion 400 comprises a plurality of via pads and associated conductive vias. In the example of FIG. 4A, via pads 230a, 230b, 230c, and 230d, and conductive vias 234a, 234b, 234c, and 234d may be in the same positions as described with reference to FIG. 2B. In the example of FIG. 4A, via pads 330e, 330f, 330g, 330h, 330i, 330j, and 330k may be in the same positions as described with reference to FIG. 3B. In addition, in FIG. 4A, conductive vias 334e, 334f, 334g, 334h, 334i, 334j, and 334k may be in the same positions as described with reference to FIG. 3B. While FIG. 4A does not show any interconnect pads 126, interconnect pads 126 are present at the top surface 107, e.g., the interconnect pads illustrated in FIGS. 1A-1G may be included in portion 400. Interconnect pads 126 are omitted from FIG. 4A for clarity. The location of conductive traces in a layer of the circuit board are depicted in FIG. 4A with dashed lines. For example, the location of conductive traces 404, 406 are illustrated in FIG. 4A. (In the example, conductive traces 404, 406 are not on top surface 107.)

FIG. 4B illustrates a plan view of a portion 401 of a layer of an apparatus and conductive vias terminating at or passing through the layer, in accordance with some embodiments. In some examples, the layer is between top surface 107 and back surface 124. While via pads are illustrated in FIG. 4B, via pads are not present in the layer. Some via pads are included in the illustration only to show their location on top surface 107 with respect to features in the layer.

A plurality of conductive vias may extend through or terminate in the layer. Any conductive vias in the layer may extend below a via pad at top surface 107. Any conductive via in the layer may under the via pad with which it is connected, such that the conductive via is within a footprint of the via pad. In various embodiments, conductive vias in the layer may be in a positional arrangement similar to or the same as via pads on at top surface 107. Portion 401 of the layer comprises conductive vias 234a, 234b, 234a, 234b, 334e, 334f, 334g, 334h, 334i, 334j, and 334k. Portion 401 of the layer also comprises one or more pairs of conductive traces 402, 404 used for conducting pair of differential signals.

Conductive vias 234a and 234b are coupled with signal via pads 230a and 230b at top surface 107 and are used for a pair of differential signals. Conductive vias 234a and 234b may be in a positional arrangement similar to or the same as via pads 230a and 230b, as described with reference to FIG. 2B. The dashed line circle surrounding conductive vias 234a and 234b represents a clearance around the vias which may be required by a design rule. Portion 401 also includes conductive vias 234c and 234d, which are coupled with ground via pads 230c and 230d at top surface 107 and are used for a ground reference signal. Conductive vias 234c and 234d may be in a positional arrangement similar to or the same as via pads 230c and 230d, as described with reference to FIGS. 2A and 2B.

Portion 401 further includes conductive vias 334e, 334f, 334g, 334h, 334i, and 334j, which are coupled with ground via pads 330e, 330f, 330g, 330h, 330i, and 330j at top surface 107 and are used for a ground reference signal. Conductive vias 334e, 334f, 334g, 334h, 334i, and 334j may be in a positional arrangement similar to or the same as via pads 330e, 330f, 330g, 330h, 330i, and 330j, as described with reference to FIG. 3B.

As illustrated in FIG. 4B, portion 401 may also include additional conductive vias extend through or terminate in the layer, e.g., conductive via 334k, which is coupled with signal via pad 330k at top surface 107. Each additional conductive via may be in a position similar to or the same as the via pad with which it is coupled at the top surface 107.

As illustrated in FIGS. 4A and 4B, the layer includes a plurality of pairs of conductive traces, each of which may be used for conducting a pair of differential signals. Each trace in a pair of conductive traces follows a path that is substantially parallel to the trace in the pair. In the illustrated example, the pairs of conductive traces follow zig-zag like paths extending between the conductive vias in a column direction, i.e., generally in the y-axis direction. The paths may curve toward or away from points between pairs of conductive vias used for differential signals. (In some embodiments, the paths may include segments that are not precisely parallel to sidewall 138 and other segments that are parallel or substantially parallel to sidewall 138.) The zig-zag like paths of pairs of conductive traces extending between the conductive vias may advantageously serve to mitigate fiber weave effect. Fibers between layers may be either parallel or substantially parallel to sidewall 138, or parallel or substantially parallel to sidewall 140. Segments of the traces that curve toward or away from points between pairs of conductive vias are not parallel to fibers and, as such, these segments may not be susceptible to fiber weave effect.

For example, the pair of conductive traces 402 and 404 follow a path extending between conductive vias 134a and 134b, and conductive via 134d. Conductive vias 134a and 134b are on a first side of the path and conductive via 134d is on a second of the side of the path opposite the first side. The conductive traces 402 and 404 follow a zig-zag path that includes, e.g., segment k1 angled toward sidewall 138 and segment k2 angled away from sidewall 138. Conductive traces 402 and 404 also includes segment k3 between conductive vias 334g and 334h, which extends in a direction angled toward sidewall 138. Conductive traces 402 and 404 further includes segment k4 between conductive vias 334e and 334f, which extends in a direction angled away from sidewall 138.

FIG. 5A illustrates a plan view of a portion 500 of a surface of an apparatus in which, in comparison with other examples described herein, particular via pads and conductive vias are omitted from regions where via pads and conductive vias could be located, in accordance with some embodiments. In some examples, the apparatus is base component 106 and the surface is a top surface 107. Portion 500 comprises a plurality of interconnect pads, via pads, and associated conductive vias. Portion 500 also includes a plurality of regions (depicted by circular dashed lines) where selected via pads and conductive vias are located in some examples described herein, but which have been omitted from the embodiment shown in FIG. 5A.

In the example of FIG. 5A, via pads 330e, 330f, 330g, 330h, 330i, 330j, and 330k may be in the same positions as described with reference to FIG. 3B. In addition, in FIG. 5A, conductive vias 334e, 334f, 334g, 334h, 334i, 334j, and 334k may be in the same positions as described with reference to FIG. 3B.

In the example of FIG. 5A, via pads 230a, 230b, and conductive vias 234b and 234b may be in the same positions as described with reference to FIG. 2B. In the examples of FIGS. 2A and 2B, via pads 230c and 230d, and conductive vias 234c and 234d are coupled with a ground reference signal to provide horizontal (x-direction) isolation for the signal via pads 230a, 230b, and conductive vias 234a and 234b. However, in comparison with the example presented in FIG. 2B, via pads 230c and 230d, and conductive vias 234c and 234d are omitted. Instead, FIG. 5A includes regions 530c and 530d (depicted by circular dashed lines) in locations where via pads 230c and 230d, and conductive vias 234c and 234d are located in FIG. 2B.

For clarity of illustration, FIG. 5A does not show all of the interconnect pads 126 that are present at the top surface 107. In some embodiments, all of the interconnect pads 126 illustrated in FIGS. 1A-1G may be present at the top surface 107. However, only selected interconnect pads 126 are shown. Specifically, the interconnect pads 126c and 126d are shown. (Interconnect pads 126c and 126d are used to couple with a ground reference signal to provide horizontal isolation.) Because selected via pads and conductive vias are not implemented in the example shown in FIG. 5, some interconnect pads will not be coupled with a via pad and conductive via. As a result, such a ground interconnect pad will not have a dedicated via pad and via to connect to. To ensure that the connection between base component 106 and another device works properly, an interconnect pad not coupled with a dedicated via pad (because its via pad was not implemented) may be connected to a nearby via pad associated with a different interconnect pad. Accordingly, this nearby via pad is shared with the interconnect pad it is dedicated to and the interconnect pad not having a dedicated via pad. In some embodiments, unconnected interconnect pads are connected to a nearby pad with a conductive feature, such as a microstrip. In the illustrated example, interconnect pad 126c is connected to via pad 330j by microstrip 508c, and interconnect pad 126d is connected to via pad 330g by microstrip 508d.

As illustrated in FIG. 5A, the location of conductive traces in a layer of the circuit board are depicted with dashed lines. For example, the location of conductive traces 504, 506 are illustrated in FIG. 5A. (In the example, conductive traces 504, 506 are not on top surface 107.)

FIG. 5B illustrates a plan view of a portion 502 of a layer of an apparatus and conductive vias terminating at or passing through the layer, in accordance with some embodiments. In some examples, the layer is between top surface 107 and back surface 124. While via pads are illustrated in FIG. 5B, via pads are not present in the layer. Some via pads are included in the illustration only to show their location on top surface 107 with respect to features in the layer.

A plurality of conductive vias may extend through or terminate in the layer. Any conductive via in the layer may extend below a via pad at top surface 107. Any conductive via in the layer may be under the via pad with which it is connected, such that the conductive via is within a footprint of the via pad. In various embodiments, conductive vias in the layer may be in a positional arrangement similar to or the same as via pads on at top surface 107. Conductive vias 234a and 234b are coupled with signal via pads 230a and 230b at top surface 107 and are used for a pair of differential signals. Conductive vias 234a and 234b may be in a positional arrangement similar to or the same as via pads 230a and 230b, as described with reference to FIG. 2B.

In comparison to portions 400, 401, the portion 502 does not include conductive vias 234c and 234d. Instead, portion 502 includes regions 530c and 530d, which may be directly below ground via pads 230c and 230d at top surface 107 and are used for a ground reference signal. Regions 530c and 530d may be in a positional arrangement similar to or the same as via pads 230c and 230d, as described with reference to FIGS. 2A and 2B. In an example, regions 530c and 530d are in locations where respective conductive vias coupled with via pads 230c and 230d would be located had they not been omitted. An advantage of omitting conductive vias 234c and 234d is that conductive traces may be routed through the regions 530c and 530d.

Portion 502 further includes conductive vias 334e, 334f, 334g, 334h, 334i, and 334j, which are coupled with ground via pads 330e, 330f, 330g, 330h, 330i, and 330j at top surface 107 and are used for a ground reference signal. Conductive vias 334e, 334f, 334g, 334h, 334i, and 334j may be in a positional arrangement similar to or the same as via pads 330e, 330f, 330g, 330h, 330i, and 330j, as described with reference to FIG. 3B.

As illustrated in FIG. 5B, portion 502 may also include additional conductive vias extend through or terminate in the layer, e.g., conductive via 334k, which is coupled with signal via pad 330k at top surface 107. Each additional conductive via may be in a position similar to or the same as the via pad with which it is coupled at the top surface 107.

Portion 502 of the layer also comprises one or more pairs of conductive traces 504, 506 used for conducting pair of differential signals. Each trace is substantially parallel to the other trace in the pair. In the illustrated example, the pairs of conductive traces follow paths extending between the conductive vias in a column direction, i.e., generally in the y-axis direction. The paths include segments angled toward or away from sidewall 138. The paths also include segments that are parallel or substantially parallel to sidewall 138. The angled segments may advantageously serve to mitigate fiber weave effect. Fibers between layers may be either parallel or substantially parallel to sidewall 138, or parallel or substantially parallel to sidewall 140. Segments of the traces angled toward or away from sidewall 138 are not parallel to fibers and, as such, these segments may not be susceptible to fiber weave effect. In some embodiments, the path of a pair of conductive traces comprises first, second, and third segments, wherein the first segment extends in a direction angled toward a sidewall, the second segment extends in a direction angled away the sidewall, and a third segment is connected between the first and second segments, the third segment extending in a direction parallel to the sidewall.

For example, the pair of conductive traces 504 and 506 follow a path extending between conductive vias 234a and 234b, and conductive vias 334f and 334g on an opposite side. Conductive vias 234a and 234b are on a first side of the path and conductive vias 334f and 334g are on a second of the side the path opposite the first side. The conductive traces 504 and 506 follow a path that includes, e.g., segment k5 angled toward sidewall 138 and segment k6 angled away from sidewall 138. Conductive traces 504 and 506 also includes segment k7, which extends in a direction angled toward sidewall 138, and a segment k8, which extends in a direction angled away from sidewall 138. The path of conducive traces 504, 506 also include segment k9, which is parallel or substantially parallel to sidewall 138. The segment k9 of conductive traces 504, 506 is routed through the region 530m. Advantageously, segment k9 is separated from nearby signal vias, e.g., conductive via 334k, by at greater distance than would be possible if the conductive via that would have been present in region 530m had not been omitted. The greater distance may make segment k9 less susceptible to crosstalk from nearby signal vias.

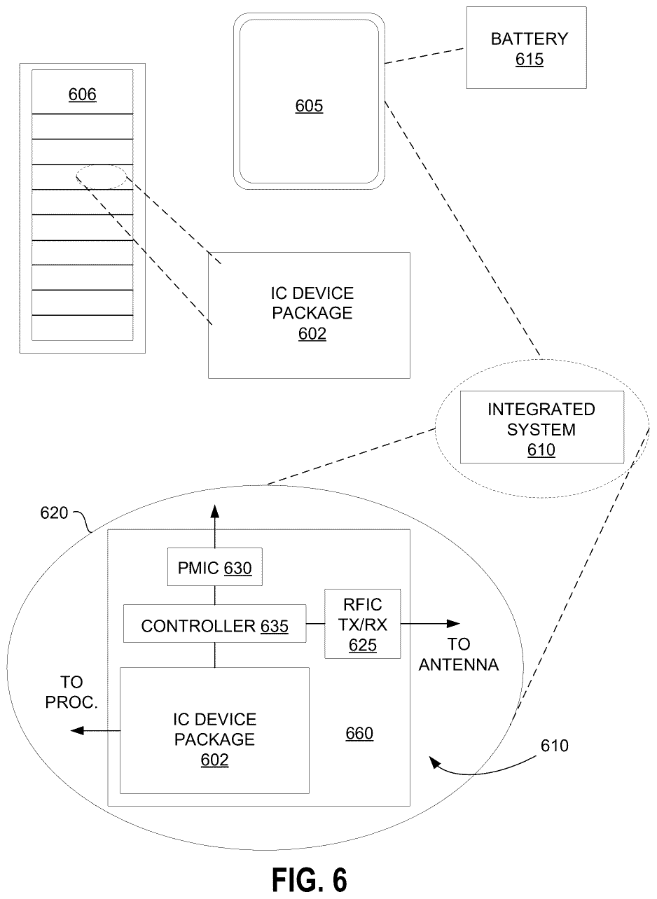

FIG. 6 illustrates a mobile computing platform and a data server machine employing an IC device or an IC device package electrically coupled to base component, the base component comprising interconnect pads that contact, intersect with, or which are spaced away from associated via pads. The via pads may be coupled with conductive vias, wherein the via pads may be in any of the positions on a surface of the base component described herein. In addition, conductive vias in a layer of the base component may be in any of the positions described herein. Server machine 606 may be any commercial server, for example including any number of high-performance computing platforms disposed within a rack and networked together for electronic data processing, which in the exemplary embodiment includes a base component comprising interconnect pads that contact, intersect with, or which are spaced away from associated via pads, wherein the via pads and conductive vias may be in any of the positions disclosed herein, for example as described elsewhere herein. The mobile computing platform 605 may be any portable device configured for each of electronic data display, electronic data processing, wireless electronic data transmission, or the like. For example, the mobile computing platform 605 may be any of a tablet, a smart phone, laptop computer, etc., and may include a display screen (e.g., a capacitive, inductive, resistive, or optical touchscreen), a chip-level or package-level integrated system 610, and a battery 615.

Whether disposed within the integrated system 610 illustrated in the expanded view 620, or as a stand-alone package within the server machine 606, the integrated system or server machine includes an IC device package 602, for example as described elsewhere herein. IC device package 602 may be further coupled to a host substrate 660, along with, one or more of a power management integrated circuit (PMIC) 630, RF (wireless) integrated circuit (RFIC) 625 including a wideband RF (wireless) transmitter and/or receiver (TX/RX) (e.g., including a digital baseband and an analog front-end module further comprises a power amplifier on a transmit path and a low noise amplifier on a receive path), and a controller 635. Host substrate 660 may be a base component comprising interconnect pads that contact, intersect with, or which are spaced away from associated via pads, wherein the via pads and conductive vias may be in any of the positions disclosed herein. PMIC 630 may perform battery power regulation, DC-to-DC conversion, etc., and so has an input coupled to battery 615 and with an output providing a current supply to other functional modules. As further illustrated, in the exemplary embodiment, RFIC 625 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

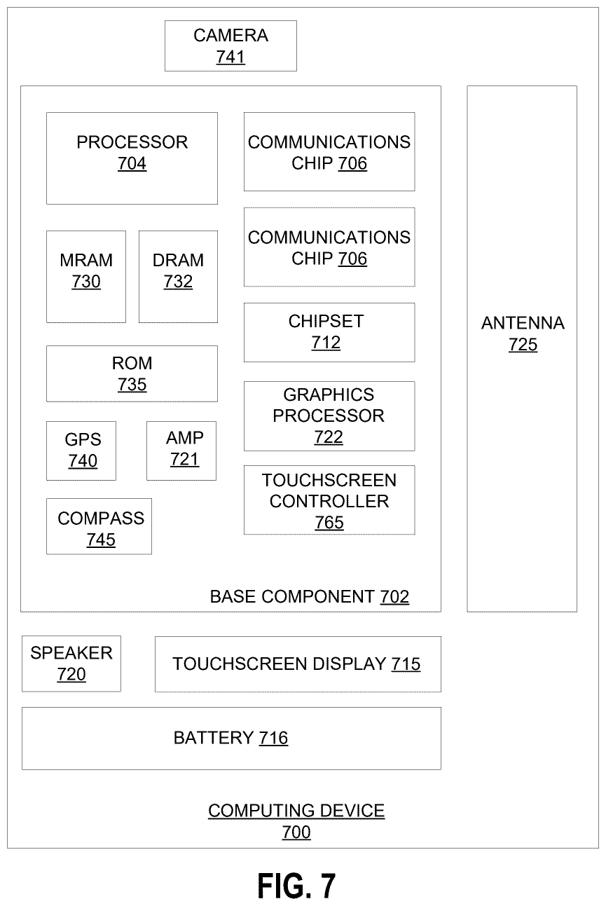

FIG. 7 is a functional block diagram of an electronic computing device 700, in accordance with an embodiment of the present invention. The computing device may include any of the devices or structures discussed elsewhere herein. Device 700 further includes a base component 702, e.g., a PCB, comprising interconnect pads that contact, intersect with, which are spaced away from associated via pads, wherein the via pads and conductive vias may be in any of the positions disclosed herein. The base component 702 may host a number of components, such as, but not limited to, a processor 704 (e.g., an applications processor). Processor 704 may be physically and/or electrically coupled to base component 702. In some examples, processor 704 is within IC device 102 or IC device package 108, for example, as described elsewhere herein. Processor 704 may be implemented with circuitry in either or both of a host IC chip and a chiplet. In general, the term “processor” or “microprocessor” may refer to any device or portion of a device that processes electronic data from registers and/or memory to transform that electronic data into other electronic data that may be further stored in registers and/or memory. In some embodiments, an IC device or package is coupled with the base component 702 with a socket.

In various examples, one or more communication chips 706 may also be physically and/or electrically coupled to the base component 702. In further implementations, communication chips 706 may be part of processor 704. Depending on its applications, computing device 700 may include other components that may or may not be physically and electrically coupled to base component 702. These other components include, but are not limited to, volatile memory (e.g., DRAM 732), non-volatile memory (e.g., ROM 735), flash memory (e.g., NAND or NOR), magnetic memory (MRAM 730), a graphics processor 722, a digital signal processor, a crypto processor, a chipset 712, an antenna 725, touchscreen display 715, touchscreen controller 765, battery 716, audio codec, video codec, power amplifier 721, global positioning system (GPS) device 740, compass 745, accelerometer, gyroscope, speaker 720, camera 741, and mass storage device (such as hard disk drive, solid-state drive (SSD), compact disk (CD), digital versatile disk (DVD), and so forth), or the like.

Communication chips 706 may enable wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 706 may implement any of a number of wireless standards or protocols. As discussed, computing device 700 may include a plurality of communication chips 706. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

Example 1: An apparatus comprising: a base component comprising a surface comprising a plurality of interconnect pads arranged in rows and columns orthogonal to the rows, wherein the interconnect pads comprise first and second interconnect pads in first and second rows in a first column; a plurality of via pads at the surface, the plurality of via pads comprising a first via pad in the first row and a second via pad in the second row; a plurality of conductive vias extending below the surface, wherein each conductive via is coupled with one of the via pads; and wherein the first via pad partially overlaps with the first interconnect pad, and the second via pad partially overlaps with the second interconnect pad.

Example 2: The apparatus of example 1, wherein: the first row comprises a first center line parallel to and bisecting the interconnect pads in the first row, and the first via pad is offset from the first center line in a first direction; the second row comprises a second center line parallel to and bisecting the interconnect pads in the second row, and the second via pad is offset from the second center line in a second direction different from the first direction.

Example 3: The apparatus of example 1 or example 2, wherein the plurality of interconnect pads further comprises a third interconnect pad and the plurality of via pads further comprises a third via pad; the third interconnect pad is in a second column adjacent to the first column and a third row between the first and second rows; and the third via pad partially overlaps with the third interconnect pad.

Example 4: The apparatus of example 1 or example 2, wherein the plurality of interconnect pads further comprises a third interconnect pad and the plurality of via pads further comprises a third via pad; the third interconnect pad is in the first column and a third row, and the third row is separated from the first row by one row; and the third row comprises a third center line parallel to and bisecting the interconnect pads in the third row, and the third via pad partially overlaps with the third interconnect pad and is vertically offset from the third center line in a direction toward the first and second rows.

Example 5: The apparatus of any one of examples 1 through 4, wherein the plurality of interconnect pads is coupled with a plurality of interconnect features of an integrated circuit device or package.

Example 6: The apparatus of any one of examples 1 through 5, wherein the first via pad partially overlaps with the first interconnect pad by a first overlap portion and the first overlap portion is less than five percent of an area of the first via pad; and the second via pad partially overlaps with the second interconnect pad by a second overlap portion and the second overlap portion is less than five percent of an area of the second via pad.

Example 7: The apparatus of any one of examples 1 through 6, wherein individual interconnect pads in a row are laterally offset from individual interconnect pads in an adjacent row.

Example 8: The apparatus of example 1, wherein the surface is a first surface and the base component comprises a second surface opposite the first surface, the plurality of interconnect pads further comprises a third interconnect pad and the plurality of via pads further comprises a third via pad, wherein the third interconnect pad is in a second column adjacent to the first column and a third row between the first and second rows; and the third via pad is in the third row and partially overlaps with the third interconnect pad; the apparatus further comprising: a layer between the first and second surfaces; a first conductive via coupled with the first via pad, a second conductive via coupled with the second via pad, and a third conductive via coupled with the third via pad, each of the first, second, and third conductive vias extending to or through the layer; a pair of conductive traces following a path extending in a column direction within the layer, wherein the first and second conductive vias are on a first side of the path and the third conductive via is on a second of the path opposite the first side; and the path comprises a first segment angled toward a sidewall of the base component and a second segment angled away from the sidewall.

Example 9: The apparatus of example 8, wherein the plurality of interconnect pads further comprises a fourth interconnect pad; the fourth interconnect pad is in the third row and a third column adjacent to the first column on a side opposite the second column; and the surface further comprises a region in the third row and proximate to the fourth interconnect pad, wherein the region does not include a via pad.

Example 10: The apparatus of example 9, wherein the pair of conductive traces is a first pair of conductive traces, further comprising a second pair of conductive traces extending in the column direction within the layer, wherein the second pair of conductive traces comprises a third segment extending in a direction parallel to the sidewall under the fourth interconnect pad or the region.

Example 11; An apparatus comprising: a base component comprising a surface comprising a plurality of interconnect pads arranged in rows and columns orthogonal to the rows, wherein the plurality of interconnect pads comprise first and second interconnect pads in first and second rows in a first column; a plurality of via pads at the surface comprising a first via pad in the first row and a second via pad in the second row; a plurality of conductive vias extending below the surface, wherein each conductive via is coupled with one of the via pads; and wherein the first via pad comprises a perimeter in contact with the first interconnect pad, and the second via pad comprises a perimeter in contact with the second interconnect pad.

Example 12: The apparatus of example 11, wherein: the first row comprises a first center line parallel to and bisecting the interconnect pads in the first row, and the first via pad is offset from the first center line; the second row comprises a second center line parallel to and bisecting the interconnect pads in the second row, and the second via pad is offset from the second center line; and a first pitch between the first and second interconnect pads is greater than a second pitch between the first and second via pads; and an integrated circuit device or package comprising a plurality of interconnect features coupled with the plurality of interconnect pads.

Example 13. The apparatus of example 12, wherein: the plurality of interconnect pads further comprises a third and a fourth interconnect pad and the plurality of via pads further comprises a third via pad; the third interconnect pad is in a third row between the first and second rows and a second column adjacent to the first column; the third via pad is in the third row and comprises a perimeter in contact with the third interconnect pad; the fourth interconnect pad is in the third row and a third column adjacent to the first column; and the surface further comprises a region in the third row adjacent to the fourth interconnect pad, wherein the region does not include a conductive via extending below the surface.

Example 14: The apparatus of example 11, wherein the plurality of interconnect pads further comprises a third interconnect pad and the plurality of via pads further comprises a third via pad; the third interconnect pad is in the first column and a third row, and the third row is separated from the first row by one row; and the third row comprises a third center line parallel to and bisecting the interconnect pads in the third row, and the third via pad comprises a perimeter in contact with the third interconnect pad and is vertically offset from the third center line in a direction toward the first and second rows.

Example 15: The apparatus of any one of examples 11 through 14, wherein the first via pad comprises a first radius, the first interconnect pad comprises a second radius, and a distance between a center of the first via pad and a center of the second via pad is approximately equal to a sum of the first and second radii.

Example 16: An apparatus comprising: an integrated circuit device or package comprising a plurality of interconnect features; a base component comprising a surface, the surface comprising a plurality of interconnect pads, wherein the interconnect pads are arranged in rows and columns orthogonal to the rows, and comprise first and second interconnect pads in first and second rows in a first column, wherein the interconnect pads are coupled with the interconnect features; a plurality of via pads at the surface comprising a first via pad in the first row and a second via pad in the second row; a plurality of conductive vias extending below the surface, wherein each conductive via is coupled with one of the via pads; wherein the first row comprises a first center line parallel to and bisecting the interconnect pads in the first row, and the first via pad is proximate the first interconnect pad and offset from the first center line in a first direction; and the second row comprises a second center line parallel to and bisecting the interconnect pads in the second row, and the second via pad is proximate the second interconnect pad and offset from the second center line in a second direction opposite the first direction.

Example 17: The apparatus of example 16, wherein: the first via pad is spaced away from the first interconnect pad by a first gap or partially overlaps the first interconnect pad by a first overlap portion; and the second via pad is spaced away from the second interconnect pad by a second gap or partially overlaps the second interconnect pad by a second overlap portion.

Example 18: The apparatus of example 17, wherein: the first overlap portion is less than five percent of an area of the first via pad or the first gap is less than eight percent of a diameter of the first via pad; and the second overlap portion is less than five percent of an area of the second via pad or the first gap is less than eight percent of a diameter of the second interconnect pad.

Example 19: The apparatus of example 18, further comprising: a third interconnect pad, wherein the third interconnect pad is in a second column adjacent to the first column and a third row between the first and second rows; and a third via pad in the third row, wherein the third via pad is spaced away from the third interconnect pad by a third gap or partially overlaps the third interconnect pad by a third overlap portion.

Example 20: The apparatus of any one of examples 16 through 19, further comprising: a fourth interconnect pad, wherein the fourth interconnect pad is in the first column and a fourth row, and the fourth row is separated from the first row by one row; and a fourth via pad, wherein the fourth via pad is spaced away from the fourth interconnect pad by a fourth gap or partially overlaps the fourth interconnect pad by a fourth overlap portion.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosure should therefore be determined with reference to the appended claims, along with the full scope of equivalents to which such claims are entitled.

What is claimed is:

1. An apparatus comprising:
a base component comprising a surface comprising a plurality of interconnect pads arranged in rows and columns orthogonal to the rows, wherein the interconnect pads comprise first and second interconnect pads in first and second rows in a first column;
a plurality of via pads at the surface, the plurality of via pads comprising a first via pad in the first row and a second via pad in the second row;
a plurality of conductive vias extending below the surface, wherein each conductive via is coupled with one of the via pads; and
wherein the first via pad partially overlaps with the first interconnect pad, and the second via pad partially overlaps with the second interconnect pad.

2. The apparatus of claim 1, wherein:
the first row comprises a first center line parallel to and bisecting the interconnect pads in the first row, and the first via pad is offset from the first center line in a first direction;
the second row comprises a second center line parallel to and bisecting the interconnect pads in the second row, and the second via pad is offset from the second center line in a second direction different from the first direction.

3. The apparatus of claim 1, wherein the plurality of interconnect pads further comprises a third interconnect pad and the plurality of via pads further comprises a third via pad;
the third interconnect pad is in a second column adjacent to the first column and a third row between the first and second rows; and
the third via pad partially overlaps with the third interconnect pad.

4. The apparatus of claim 1, wherein the plurality of interconnect pads further comprises a third interconnect pad and the plurality of via pads further comprises a third via pad;
the third interconnect pad is in the first column and a third row, and the third row is separated from the first row by one row; and
the third row comprises a third center line parallel to and bisecting the interconnect pads in the third row, and the third via pad partially overlaps with the third interconnect pad and is vertically offset from the third center line in a direction toward the first and second rows.

5. The apparatus of claim 1, wherein the plurality of interconnect pads is coupled with a plurality of interconnect features of an integrated circuit device or package.

6. The apparatus of claim 1, wherein the first via pad partially overlaps with the first interconnect pad by a first overlap portion and the first overlap portion is less than five percent of an area of the first via pad; and
the second via pad partially overlaps with the second interconnect pad by a second overlap portion and the second overlap portion is less than five percent of an area of the second via pad.

7. The apparatus of claim 1, wherein individual interconnect pads in a row are laterally offset from individual interconnect pads in an adjacent row.

8. The apparatus of claim 1, wherein the surface is a first surface and the base component comprises a second surface opposite the first surface, the plurality of interconnect pads further comprises a third interconnect pad and the plurality of via pads further comprises a third via pad,
wherein the third interconnect pad is in a second column adjacent to the first column and a third row between the first and second rows; and
the third via pad is in the third row and partially overlaps with the third interconnect pad;
the apparatus further comprising:
a layer between the first and second surfaces;
a first conductive via coupled with the first via pad, a second conductive via coupled with the second via pad, and a third conductive via coupled with the third via pad, each of the first, second, and third conductive vias extending to or through the layer;
a pair of conductive traces following a path extending in a column direction within the layer, wherein the first and second conductive vias are on a first side of the path and the third conductive via is on a second of the path opposite the first side; and
the path comprises a first segment angled toward a sidewall of the base component and a second segment angled away from the sidewall.

9. The apparatus of claim 8, wherein the plurality of interconnect pads further comprises a fourth interconnect pad;
the fourth interconnect pad is in the third row and a third column adjacent to the first column on a side opposite the second column; and
the surface further comprises a region in the third row and proximate to the fourth interconnect pad, wherein the region does not include a via pad.

10. The apparatus of claim 9, wherein the pair of conductive traces is a first pair of conductive traces, further comprising a second pair of conductive traces extending in the column direction within the layer, wherein the second pair of conductive traces comprises a third segment extending in a direction parallel to the sidewall under the fourth interconnect pad or the region.

11. An apparatus comprising:
a base component comprising a surface comprising a plurality of interconnect pads arranged in rows and columns orthogonal to the rows, wherein the plurality of interconnect pads comprise first and second interconnect pads in first and second rows in a first column;
a plurality of via pads at the surface comprising a first via pad in the first row and a second via pad in the second row;
a plurality of conductive vias extending below the surface, wherein each conductive via is coupled with one of the via pads; and
wherein the first via pad comprises a perimeter in contact with the first interconnect pad, and the second via pad comprises a perimeter in contact with the second interconnect pad.

12. The apparatus of claim 11, wherein:
the first row comprises a first center line parallel to and bisecting the interconnect pads in the first row, and the first via pad is offset from the first center line;
the second row comprises a second center line parallel to and bisecting the interconnect pads in the second row, and the second via pad is offset from the second center line; and
a first pitch between the first and second interconnect pads is greater than a second pitch between the first and second via pads; and
an integrated circuit device or package comprising a plurality of interconnect features coupled with the plurality of interconnect pads.

13. The apparatus of claim 12, wherein:
the plurality of interconnect pads further comprises a third and a fourth interconnect pad and the plurality of via pads further comprises a third via pad;
the third interconnect pad is in a third row between the first and second rows and a second column adjacent to the first column;
the third via pad is in the third row and comprises a perimeter in contact with the third interconnect pad;
the fourth interconnect pad is in the third row and a third column adjacent to the first column; and
the surface further comprises a region in the third row adjacent to the fourth interconnect pad, wherein the region does not include a conductive via extending below the surface.

14. The apparatus of claim 11, wherein the plurality of interconnect pads further comprises a third interconnect pad and the plurality of via pads further comprises a third via pad;
the third interconnect pad is in the first column and a third row, and the third row is separated from the first row by one row; and
the third row comprises a third center line parallel to and bisecting the interconnect pads in the third row, and the third via pad comprises a perimeter in contact with the third interconnect pad and is vertically offset from the third center line in a direction toward the first and second rows.

15. The apparatus of claim 11, wherein the first via pad comprises a first radius, the first interconnect pad comprises a second radius, and a distance between a center of the first via pad and a center of the second via pad is approximately equal to a sum of the first and second radii.

16. An apparatus comprising:
an integrated circuit device or package comprising a plurality of interconnect features;
a base component comprising a surface, the surface comprising a plurality of interconnect pads, wherein the interconnect pads are arranged in rows and columns orthogonal to the rows, and comprise first and second interconnect pads in first and second rows in a first column, wherein the interconnect pads are coupled with the interconnect features;
a plurality of via pads at the surface comprising a first via pad in the first row and a second via pad in the second row;
a plurality of conductive vias extending below the surface, wherein each conductive via is coupled with one of the via pads;
wherein the first row comprises a first center line parallel to and bisecting the interconnect pads in the first row, and the first via pad is proximate the first interconnect pad and offset from the first center line in a first direction; and
the second row comprises a second center line parallel to and bisecting the interconnect pads in the second row, and the second via pad is proximate the second interconnect pad and offset from the second center line in a second direction opposite the first direction.

17. The apparatus of claim 16, wherein:
the first via pad is spaced away from the first interconnect pad by a first gap or partially overlaps the first interconnect pad by a first overlap portion; and
the second via pad is spaced away from the second interconnect pad by a second gap or partially overlaps the second interconnect pad by a second overlap portion.

18. The apparatus of claim 17, wherein:
the first overlap portion is less than five percent of an area of the first via pad or the first gap is less than eight percent of a diameter of the first via pad; and
the second overlap portion is less than five percent of an area of the second via pad or the first gap is less than eight percent of a diameter of the second interconnect pad.

19. The apparatus of claim 18, further comprising:
a third interconnect pad, wherein the third interconnect pad is in a second column adjacent to the first column and a third row between the first and second rows; and
a third via pad in the third row, wherein the third via pad is spaced away from the third interconnect pad by a third gap or partially overlaps the third interconnect pad by a third overlap portion.

20. The apparatus of claim 18, further comprising:
a fourth interconnect pad, wherein the fourth interconnect pad is in the first column and a fourth row, and the fourth row is separated from the first row by one row; and
a fourth via pad, wherein the fourth via pad is spaced away from the fourth interconnect pad by a fourth gap or overlaps the fourth interconnect pad by a fourth overlap portion.
